(19) United States
(12) Patent Application Publication
(10) Pub. No.: US 2025/0386715 A1
(43) Pub. Date: Dec. 18, 2025

(54) DISPLAY DEVICE

(71) Applicant: Samsung Display Co., Ltd., Yongin-Si (KR)

(72) Inventors: Hyun Woo NOH, Yongin-si (KR); Hyo Joon KIM, Yongin-si (KR); Keun Young PARK, Yongin-si (KR); Moon Jung BAEK, Yongin-si (KR); Dae Ho LEE, Yongin-si (KR)

(21) Appl. No.: 19/021,155

(22) Filed: Jan. 15, 2025

(30) Foreign Application Priority Data
Jun. 12, 2024 (KR) 10-2024-0076533

(51) Int. Cl. H10K 59/80; H10K 59/38

(52) U.S. Cl. CPC H10K 59/8731; H10K 59/38

(57) ABSTRACT

A display device includes light emitting elements a substrate, an encapsulation layer enclosing the light emitting elements, a color conversion layer on the encapsulation layer, a first capping layer on the color conversion layer, a low refractive layer on the color conversion layer, a second capping layer on the low refractive layer, a color filter layer on the second capping layer, a planarization layer on the color filter layer, a first upper inorganic encapsulation layer on the planarization layer, and an outermost dam. An organic encapsulation layer is between a first and a second inorganic encapsulation layers, the color filter layer and the planarization layer are inside of the outermost dam, the first upper inorganic encapsulation layer covers a side surface and an end portion of the planarization layer where the first upper inorganic encapsulation layer contacts the second capping layer.

### CROSS-REFERENCE TO RELATED APPLICATION

This application claims priority to and the benefit of Korean Patent Application No. 10-2024-0076533 filed in the Korean Intellectual Property Office on Jun. 12, 2024, the entire contents of which are incorporated herein by reference.

### BACKGROUND

### 1. Field

The present disclosure relates to display devices.

### 2. Description of the Related Art

A type of flat panel display, the organic light emitting element OLED display, is a self-luminous display device that exhibits excellent characteristics in terms of low power consumption, high luminance, and fast response speed, while also being capable of multi-color display. Recently, a hybrid technology that applies quantum dots to organic light emitting element OLED type displays has attracted attention. Quantum dots are nanometer-sized semiconductor crystals, and the energy band gap of the quantum dots may be adjusted according to the size and shape of the quantum dots. When semiconductor materials such as quantum dots are reduced to nanometer sizes, they have the potential to be a next generation display material because they have high luminous efficiency and narrow full width at half maximum in the visible light region.

### SUMMARY

The present disclosure is to provide a display device having an excellent sealing characteristic at the top and side edges to prevent infiltration of impurities from the surrounding environment.

A display device according to an embodiment may include a substrate, a plurality of light emitting elements disposed in a display area on the substrate, an encapsulation layer that encloses the plurality of light emitting elements, a color conversion layer and a bank disposed on the encapsulation layer, a first capping layer disposed on the color conversion layer and the bank, a low refractive layer disposed on the color conversion layer and the bank, a second capping layer disposed on the low refractive layer, a color filter layer disposed on the second capping layer, a planarization layer disposed on the color filter layer, a first upper inorganic encapsulation layer disposed on the planarization layer, and an inner dam and an outermost dam which are disposed in a non-display area of the substrate, wherein the encapsulation layer includes an organic encapsulation layer disposed between a first inorganic encapsulation layer and a second inorganic encapsulation layer, wherein the color filter layer and the planarization layer are disposed inside of the outermost dam, wherein the first upper inorganic encapsulation layer covers a side surface and an end portion of the planarization layer, and wherein the first upper inorganic encapsulation layer contacts the second capping layer at an end portion of the planarization layer.

The low refractive layer may be disposed inside of the outermost dam, the first capping layer, and the first capping layer and the second capping layer may contact each other at an end portion of the low refractive layer.

The display device may further include an upper organic encapsulation layer disposed on the first upper inorganic encapsulation layer and a second upper inorganic encapsulation layer disposed on the upper organic encapsulation layer, wherein the upper organic encapsulation layer may be disposed inside of the outermost dam, wherein the second upper inorganic encapsulation layer may cover an end portion of the upper organic encapsulation layer.

The first upper inorganic encapsulation layer and the second upper inorganic encapsulation layer may contact with each other at an end portion of the organic encapsulation layer.

The display device may further include a stopper dam disposed in a non-display area adjacent to the upper organic encapsulation layer, wherein the upper organic encapsulation layer may be disposed inside of the stopper dam, and the second upper inorganic encapsulation layer may cover upper surface and side surface of the stopper dam.

The first capping layer may cover the bank and the color conversion layer and a side surface of the bank, wherein the first capping layer and the second inorganic encapsulation layer may contact with each other at an end portion of the bank.

The second inorganic encapsulation layer may cover a side surface of the organic encapsulation layer, wherein the first inorganic encapsulation layer and the second inorganic encapsulation layer may contact an upper portion of the inner dam.

The display device may further include at least one of another inner dam disposed in the non-display area outside of the dam, and an extra inner dam disposed in the non-display area inside of the inner dam.

A display device according to an embodiment may include a substrate; a plurality of light emitting elements disposed in a display area on the substrate; an encapsulation layer that encloses the plurality of light emitting elements; a color conversion layer and a bank disposed on the encapsulation layer; a first capping layer disposed on the color conversion layer and the bank; a low refractive layer disposed on the color conversion layer and the bank; a second capping layer disposed on the low refractive layer; a color filter layer disposed on the second capping layer; a planarization layer disposed on the color filter layer; a first upper inorganic encapsulation layer disposed on the planarization layer; and an inner dam and an outermost dam disposed in a non-display area of the substrate wherein the encapsulation layer includes an organic encapsulation layer disposed between a first inorganic encapsulation layer and a second inorganic encapsulation layer, wherein the planarization layer and the low refractive layer are disposed inside of the outermost dam, and wherein the first upper inorganic encapsulation layer contacts the first capping layer.

The second capping layer and the planarization layer may contact each other.

The first capping layer may cover the bank and the color conversion layer and a side surface of the bank, wherein the first capping layer and the second inorganic encapsulation layer may contact each other.

The second inorganic encapsulation layer may cover an end portion of the organic encapsulation layer, and the first inorganic encapsulation layer and the second inorganic encapsulation layer contact each other at an upper portion of the dam.

The display device may further include an upper organic encapsulation layer on the first upper inorganic encapsulation layer, and a second upper inorganic encapsulation layer disposed on the upper organic encapsulation layer, wherein upper organic encapsulation layer is disposed inside of the outermost dam, the second upper inorganic encapsulation layer covers an end portion of the upper organic encapsulation layer, wherein the first upper inorganic encapsulation layer and the second upper inorganic encapsulation layer contact each other at an end portion of the organic encapsulation layer.

The display device may include a stopper dam disposed in the non-display area adjacent to the upper organic encapsulation layer, wherein the upper organic encapsulation layer may be disposed inside of the stopper dam, and wherein the second upper inorganic encapsulation layer may cover an upper surface and a side surface of the stopper dam.

The planarization layer may be disposed inside of the stopper dam.

An electronic device according to an embodiment may include a substrate, a plurality of light emitting elements disposed in a display area on the substrate, an encapsulation layer enclosing the plurality of light emitting elements, a color conversion layer and a bank disposed on the encapsulation layer, a color filter layer disposed on the bank, a planarization layer disposed on the color filter layer, a first upper inorganic encapsulation layer disposed on the planarization layer, and an inner dam and an outermost dam disposed in a non-display area of the substrate, wherein the encapsulation layer includes a structure in which an organic encapsulation layer is disposed between the first inorganic encapsulation layer and the second inorganic encapsulation layer, wherein the planarization layer is disposed inside of the outermost dam, and the first upper inorganic encapsulation layer may contact the second inorganic encapsulation layer at an end portion of the planarization layer.

The second inorganic encapsulation layer may cover a side surface of the organic encapsulation layer, wherein the first inorganic encapsulation layer and the second inorganic encapsulation layer may contact each other at an upper portion of the inner dam.

The color filter layer may be disposed inside of the outermost dam, wherein the planarization layer may cover an end portion of the color filter layer.

The display device may include an upper organic encapsulation layer on the first upper inorganic encapsulation layer, and a second upper inorganic encapsulation layer on the upper organic encapsulation layer, wherein the upper organic encapsulation layer is disposed inside of the outermost dam, wherein the second upper inorganic encapsulation layer covers an end portion of the upper organic encapsulation layer, wherein the first upper inorganic encapsulation layer and the second upper inorganic encapsulation layer may contact each other at an end portion of the planarization layer.

The electronic device may include a stopper dam disposed in non-display area adjacent to the upper organic encapsulation layer, wherein the upper organic encapsulation layer may be disposed inside of the stopper dam, wherein the second upper inorganic encapsulation layer may cover an upper surface and a side surface of the stopper dam.

As described above, according to the present disclosure, an upper encapsulation layer is disposed on the top of a display device. The upper encapsulation layer may be in contact with the encapsulation layer disposed on organic light emission layer and inorganic encapsulation layer that caps the low refractive layer, on the side surface of an non-display portion. Accordingly, a phenomenon in which moisture flows into the display device may be prevented by disposing a structure in which the inorganic layer and the inorganic layer are in contact with each other at the outer edge of the side.

### BRIEF DESCRIPTION OF THE DRAWINGS

FIG. 1 is a schematic exploded perspective view of a display device according to an embodiment.

FIG. 2 is a schematic cross-sectional view of a display panel according to an embodiment.

FIG. 3 is a cross-sectional view of a non-display portion of a display device according to an embodiment.

FIG. 4 is an enlarged cross-sectional view of portion A of FIG. 3.

FIG. 5 is a cross-sectional view of an embodiment including a small number of dams in the embodiment of FIG. 3.

FIGS. 6 to 7 are cross-sectional views according to another embodiment related to FIG. 3.

FIG. 8 is a cross-sectional view of a non-display portion of a display device including a B portion.

FIGS. 9 to 10 are cross-sectional views of a display device including a modified structure according to an embodiment.

FIG. 11 is a cross-sectional view of a non-display portion of a display device including an E portion.

FIG. 12 is an enlarged cross-sectional view of portion E of FIG. 11.

FIGS. 13 to 15 are cross-sectional views according to another embodiment related to FIG. 10.

FIG. 16 is a cross-sectional view of a display portion of a display panel according to an embodiment.

### DETAILED DESCRIPTION

Hereinafter, various embodiments of the present disclosure will be described in detail with reference to the accompanying drawings so that those of ordinary skill in the technical field to which the present disclosure belongs can easily implement it. The present disclosure may be implemented in various different disposes and is not limited to the embodiments described herein.

In order to clearly describe the present disclosure, information irrelevant to the description are omitted, and the same reference numerals are applied to the same or similar components throughout the specification.

In addition, the size and thickness of each component shown in the drawing are arbitrarily expressed for convenience of explanation, so this disclosure is not necessarily limited to the illustration. In order to clearly express various layers and regions in the drawing, the thickness was enlarged and displayed. And in the drawing, for convenience of explanation, the thickness of some layers and areas is exaggerated.

In addition, an element such as a layer, layer, region, or substrate being referred to as “above” or “on” another element may include not only the case where the element is “directly on” another element but also the case where there is a third element in between the two elements. In contrast, an element being referred to as “directly on” another element means that there is no intervening element between the two elements. In addition, being disposed “above” or “on” a reference part means being disposed on one side of the reference part and does not necessarily mean being disposed “above” or “on” the reference part in the opposite direction of gravity.

In addition, throughout the specification, a part “including” or “comprising” a component, unless specifically stated otherwise, means that the part may include the component and additional components that are not explicitly mentioned.

In addition, throughout the specification, the phrase “on a plane” refers to a view of the target part from above, and the phrase “cross-section” refers to a view of the target part from the side.

Throughout the specification, the direction perpendicular to the main surface (wide flat surface) of the display panel is defined as the “thickness direction,” and the direction parallel to the main surface is defined as the “planar direction.”

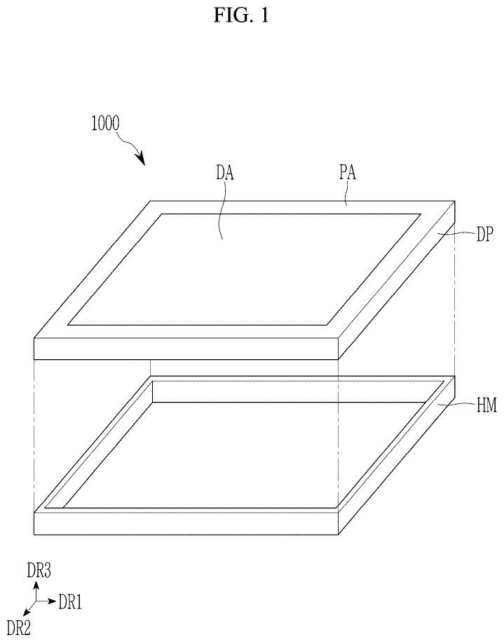

Hereinafter, a display device according to an embodiment will be described with reference to FIG. 1. FIG. 1 is a schematic exploded perspective view of a display device according to an embodiment.

Referring to FIG. 1, the display device 1000 according to an embodiment may include a display panel DP and a housing HM.

One surface on which an image is displayed in the display panel DP is parallel to a surface defined by the first direction DR1 and the second direction DR2. The normal direction of the one surface in which the image is displayed, that is, the thickness direction of the display panel DP, is indicated by the third direction DR3. The front surface (or upper surface) and the rear surface (or lower surface) of each member are at different points along the third direction DR3.

The display panel DP may be a flat rigid display panel but is not limited thereto. For example, the display panel DP may be a flexible display panel. Meanwhile, the display panel DP may be an organic light emitting display panel. However, the type of display panel DP is not limited thereto and may be disposed of various types of panels. For example, the display panel DP may be a liquid crystal display panel, an electrophoretic display panel, an electrowetting display panel, or the like. In addition, the display panel DP may be a next generation display panel such as a micro light emitting element display panel, a quantum dot light emitting element display panel, and a quantum dot organic light emitting element display panel.

As shown in FIG. 1, the display panel DP includes a display area DA in which an image is displayed, and a non-display area PA adjacent to the display area DA. The non-display area PA is an area in which an image is not displayed. The display area DA may have, for example, a rectangular shape, and the non-display area PA may have a shape surrounding the display area DA. However, the present disclosure is not limited thereto, and the shapes of the display area DA and the non-display area PA may be relatively designed.

The housing HM provides a inner space. The display panel DP is mounted inside the housing HM. In addition to the display panel DP, various electronic components, for example, a power supply unit, a storage device, an acoustic input/output module, and the like may be mounted inside the housing HM.

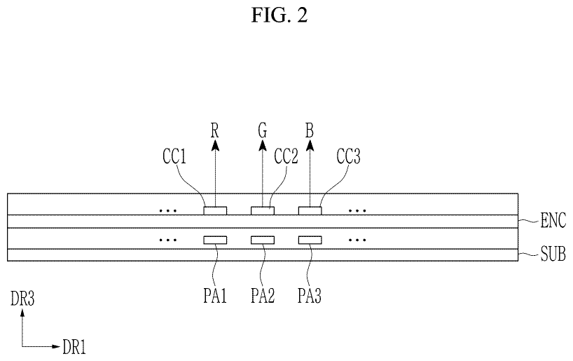

Hereinafter, a display area of a display panel according to an embodiment will be described with reference to FIG. 2. FIG. 2 is a schematic cross-sectional view of a display panel according to an embodiment.

Referring to FIG. 2, a plurality of pixels PA1, PA2, and PA3 may be disposed on the substrate SUB corresponding to the display area DA of FIG. 1. Each of the pixels PA1, PA2, and PA3 may include a plurality of transistors and a light emitting element connected thereto.

Although the present specification describes an embodiment in which a plurality of pixels PA1, PA2, and PA3 are repeatedly disposed in a stripe shape, the present disclosure is not limited thereto, and the shape and arrangement of each pixel may be variously modified.

An encapsulation layer ENC may be disposed on a plurality of pixels PA1, PA2, and PA3. The display area DA may be protected from outside air or moisture through the encapsulation layer ENC. The encapsulation layer ENC may be integrally provided to overlap the entire area of the display area DA, and may be partially disposed in the non-display area PA.

A first color conversion unit CC1, a second color conversion unit CC2, and a transmission unit CC3 may be disposed on the encapsulation layer ENC. The first color conversion unit CC1 may overlap the first pixel PA1, the second color conversion unit CC2 may overlap the second pixel PA2, and the transmission unit CC3 may overlap the third pixel PA3.

Light emitted from the first pixel PA1 may pass through the first color conversion unit CC1 to provide red light R. Light emitted from the second pixel PA2 may pass through the second color conversion unit CC2 to provide green light G. Light emitted from the third pixel PA3 may pass through the transmission unit CC3 to provide blue light B.

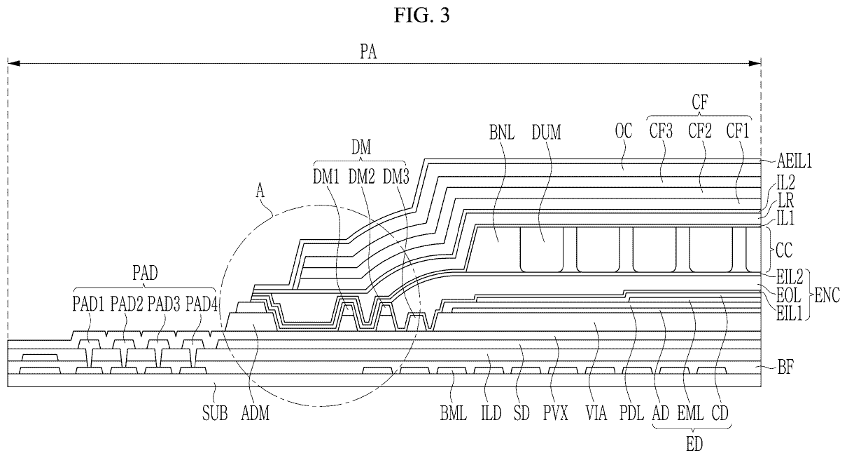

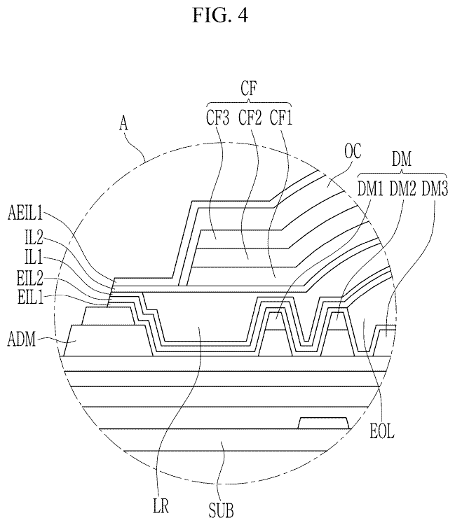

Hereinafter, a structure of a non-display area of a display panel according to an embodiment will be described in more detail with reference to FIG. 3 and FIG. 4. FIG. 3 is a cross-sectional view of a non-display part of a display device according to an embodiment, and FIG. 4 is an enlarged cross-sectional view of part A of FIG. 3.

First, the structure of the non-display area PA according to an embodiment will be described with reference to FIG. 3.

The display unit DC according to an embodiment includes a substrate SUB. The substrate SUB may include a glass material, or a flexible material such as a plastic that can bend, fold or curl.

At least one pad PAD may be disposed at an outermost portion of the non-display area PA of the substrate SUB. In the embodiment of FIG. 3, there are a first pad PAD1, a second pad PAD2, a third pad PAD3, and a fourth pad PAD4, collectively referred to as pad PAD. The inventive concept is not limited to any particular number of pads as long as there is at least one.

A buffer layer BF may be disposed on the substrate SUB. The buffer layer BF is an inorganic material, such as silicon nitride (SiNₓ) or silicon oxide (SiO₂) and may include a single layer or multiple layers. The buffer layer BF is disposed between the substrate SUB and the semiconductor layer ACT, and thus it serves to block impurities from the substrate SUB during the crystallization process when polycrystalline silicon is formed. This improves the properties of polycrystalline silicon and flattens the substrate SUB to relieve the stress on the semiconductor layer ACT disposed on the buffer layer BF.

A bottom metal layer BML may disposed on the substrate. The bottom metal layer BML may be made of multiple layered of metal, and the bottom metal layer BML may reduce interference of electrical signals and may provide electrical connection through connections with transistors, contact holes, vias, and the like. The bottom metal layer BML may include a metal material such as copper (Cu), aluminum (Al), molybdenum (Mo), silver (Ag), and the like. The bottom metal layer BML serves to transmit an electrical signal to the light emission layer EML and maintain stability through thermal management of the device.

An interlayer insulating layer ILD, and a source/drain electrode SD and a passivation PVX covering the source/drain electrode SD is disposed on the buffer layer.

Although not shown in the drawings, a gate electrode may be disposed on the buffer layer BF. The gate electrode may include Au, Ag, Cu, Ni, Pt, Pd, Al, and Mo, and may include an alloy such as Al: Nd, Mo: W alloy, etc., but is not limited thereto and may be formed of various materials in consideration of design conditions.

An interlayer insulating layer ILD may be disposed above the gate electrode. The interlayer insulating layer ILD is disposed to correspond to the entire surface of the substrate SUB. That is, it is disposed to correspond to both the display area and the non-display area PA. The interlayer insulating layer ILD may include an inorganic material such as SiNₓ, SiO₂, and may be disposed as a single layer or a two-layer structure with a SiNₓ layer and a SiO₂ layer. The interlayer insulating layer ILD is disposed between the gate electrode and the source/drain electrode SD to insulate between them.

A source/drain electrode SD may be disposed on the interlayer insulating layer ILD. Specifically, the interlayer insulating layer ILD is disposed to expose the source region and drain region disposed on the gate electrode, and the source/drain electrode SD is disposed to contact the exposed source region and drain region.

A passivation PVX may be disposed above the source/drain electrode SD. The passivation PVX may cover the interlayer insulating layer ILD and the source/drain electrode SD. The source/drain electrode SD covers less than all of the interlayer insulating layer ILD.

The passivation PVX may include either an inorganic insulating layer or an organic insulating layer. The inorganic insulating layer may include SiO₂, SiN, SiO_{N}, Al₂O₃, TiO₂, Ta₂O₅, HfO₂, ZrO₂, BST, PZT, and the like. The organic insulating layer may include general-purpose polymer (PMMA, PS), a polymer derivative having a phenol-based group, an acrylic-based polymer, an imide-based polymer, an aryl ether-based polymer, an amide-based polymer, a fluorine-based polymer, a p-xylene-based polymer, a vinyl alcohol-based polymer, and a blend thereof. In addition, the passivation PVX may include a composite laminate of an inorganic insulating layer and an organic insulating layer.

A via hole layer VIA and a pixel defining layer PDL are disposed on the passivation PVX. The via hole layer VIA and the pixel defining layer PDL comprises an organic insulating material.

Although not explicitly shown, the pixel defining layer PDL may have a pixel opening part defining a light emitting area. The pixel defining layer PDL may include an organic material such as polyacrylates resin and polyimide resin, or a silica-based inorganic material.

The pixel electrode disposed on the passivation PVX may include a reflective layer that included Ag, Mg, Al, Pt, Pd, Au, Ni, Nd, Ir, Cr, and compounds thereof, and a transparent or translucent electrode layer disposed on the reflective layer. The transparent or translucent electrode layer may include at least one selected from the group consisting of indium tin oxide ITO, indium zinc oxide IZO, zinc oxide ZnO, indium oxide In₂O₃, indium gallium oxide IGO, and aluminum zinc oxide AZO.

A light emitting element ED connected to the pixel electrode may be disposed on the pixel opening part. The light emitting element ED may include an anode AD and a cathode CD disposed to overlap the pixel electrode, and a light emission layer EML including a small molecule organic material or a polymer organic material. In addition to the organic light emission layer such as the anode AD and the cathode CD, the light emitting element ED may selectively further include a functional layer such as a hole transport layer, a hole injection layer, an electron transport layer, and an electron injection layer.

An encapsulation layer ENC may be disposed on the light emitting element ED. The encapsulation layer ENC may cover not only the upper surface of the display layer including the light emitting element ED but also the upper surface of the organic material layer under the light emitting element ED to seal the display layer.

The encapsulation layer ENC may include a single layer or a plurality of layers and may be include a composite layer including either an inorganic layer and or organic layer.

In the embodiment of FIG. 3, the encapsulation layer ENC covering the light emitting element ED may sequentially include a first inorganic encapsulation layer EIL1, an organic encapsulation layer EOL, and a second inorganic encapsulation layer EIL2.

The first inorganic encapsulation layer EIL1 may further cover a part of the upper portion of the insulating layer of the via hole VIA disposed at the upper portion of the light emitting element ED and the lower portion of the light emitting element ED and a part of the upper portion of the passivation PVX. The first inorganic encapsulation layer EIL1 may include the same material as the via hole layer VIA and the passivation PVX. That is, when the first inorganic encapsulation layer EIL1 includes SiNₓ, and the via hole VIA and the passivation PVX also include SiNₓ as described above, the bonding strength between the first inorganic encapsulation layer EIL1, the via hole VIA, and the passivation PVX may be improved. Accordingly, peeling of the first inorganic encapsulation layer EIL1 may be prevented, thereby effectively preventing penetration of external moisture or oxygen.

The organic encapsulation layer EOL is disposed on the first inorganic encapsulation layer EIL1 and may have to have a thickness to planarize the step difference by the pixel defining layer PDL.

The organic encapsulation layer EOL may cover the first inorganic encapsulation layer EIL1. When the first inorganic encapsulation layer EIL1 and the second inorganic encapsulation layer EIL2 include different materials, peeling may occur in the contact portion between the inorganic encapsulation layers due to the weak adhesive force between these inorganic encapsulation layers. Accordingly, the first inorganic encapsulation layer EIL1 may include the same material as the second inorganic encapsulation layer EIL2. Therefore, a contact failure between the first inorganic encapsulation layer EIL1 and the second inorganic encapsulation layer EIL2 does not occur, thereby effectively preventing the penetration of external moisture or oxygen.

The organic encapsulation layer EOL may include at least one of epoxy, acrylate, and urethane acrylate. The organic encapsulation layer EOL is injected into the display device by an inkjet process. Accordingly, it is disposed only inside of the second dam DM2, since the second dam DM2 restricts the area where the organic encapsulation layer EOL is formed. As used herein, each of the first dam DM1, the second dam DM2, and the third dam DM3 is an “inner dam DM” located inside of the outermost dam ADM. As used herein, a first component being “inside of” a second component indicates that the first component is closer to the display area DA than the second component in either the first direction DR1 or the second direction DR2. A first component being “outside of” a second component indicates that the first component is closer to the outer edge of the non-display area PA than the second component in either the first direction DR1 or the second direction DR2.

The second inorganic encapsulation layer EIL2 is disposed around the organic encapsulation layer EOL. The second inorganic encapsulation layer EIL2 may include, for example, SiNₓ, and may be formed by chemical vapor deposition (CVD). In addition, the second inorganic encapsulation layer EIL2 is in contact with the first inorganic encapsulation layer EIL2 at the upper portion of the first dam DM1.

A color conversion layer CC is disposed on the encapsulation layer ENC.

The color conversion layer CC may include a bank BNL disposed on the encapsulation layer ENC. The bank BNL of the display area has an opening part divided by a partition wall. Although not shown in the drawings, the opening part of the display area may include a color conversion layer, and the color conversion layer may include a base resin and quantum dots included in the base resin. The opening part of the non-display area PA includes a dummy DUM. The dummy DUM may include a material such as a material filled in the color conversion layer.

A first capping layer IL1 may be disposed on the bank BNL. The first capping layer IL1 may cover the partition wall, the color conversion layer CC, and the dummy DUM of the bank BNL. The first capping layer IL1 is an inorganic layer. The first capping layer IL1 may include at least one of aluminum oxide, titanium oxide, silicon oxide, silicon nitride, silicon oxynitride, zirconium oxide, and hafnium oxide. The first capping layer IL1 serves to cover and protect a color conversion layer made of an organic material such as quantum dots and a base resin with an inorganic layer. However, in some other embodiments, the first capping layer IL1 may be omitted.

A low refractive layer LR may be disposed on the first capping layer IL1. The low refractive layer LR may include hollow inorganic particles and a matrix part filling between the hollow inorganic particles.

The matrix part may include at least one of polymer materials selected from an acrylic polymer, a silicon polymer, a urethane polymer, and an imide polymer. For example, the matrix part may include at least one polymer material selected from acrylic-based polymers, silicone-based polymers, urethane-based polymers, and imide-based polymers, or a combination of multiple selected polymer materials.

Since the low refractive layer LR has a relatively low refractive index compared to the color conversion layer, it serves to reduce the step difference of the color conversion layer by securing the spreadability of light in the display unit of the display device. However, according to an embodiment, the low refractive layer LR may be omitted.

A second capping layer IL2 may be disposed on the low refractive layer LR. The second capping layer IL2 may cover the low refractive layer LR. The second capping layer IL2 is an inorganic layer and may include the same material as the first capping layer IL1. It serves to protect the low refractive layer LR, which may include organic materials, by covering it with an inorganic layer. However, according to an embodiment, the second capping layer IL2 may be omitted.

A color filter layer CF is disposed on the second capping layer IL2. The color filter layer CF may include the first color filter CF1, the second color filter CF2, and the third color filter CF3 to overlap the entire surface of the non-display area PA. The first color filter CF1, the second color filter CF2, and the third color filter CF3 may serve as a light blocking member so that the non-display area PA is not visible.

A planarization layer OC may be further disposed on the color filter layer CF. The planarization layer (OC) is an organic layer and may include at least one of materials selected from the group consisting of acrylic, methacrylic, polyester, polyethylene, polypropylene, polyethylene terephthalate, polyethylene naphthalate, polycarbonate, polyimide, polyethylene sulfonate, polyoxymethylene, polyarylate, and hexamethyldisiloxane.

A first upper inorganic layer AEIL1 is disposed on the planarization layer OC. The first upper inorganic layer AEIL1 covers the upper and side surfaces of the planarization layer OC and is in contact with another inorganic layer (in FIG. 3, the second capping layer IL2), serving as a protective barrier to prevent oxygen or moisture from penetrating the organic planarization layer OC. In addition to the first upper inorganic layer AEIL1, a plurality of additional inorganic layers and organic layers alternately disposed at the top of the display device may be further included.

With reference to FIG. 4, a structure of a side surface part on the display cross-sectional structure including the first upper inorganic layer AEIL1 will be described in more detail.

The first inorganic encapsulation layer EIL1 and the second inorganic encapsulation layer EIL2 extend in contact with each other and are disposed up to the upper surface of the outermost dam ADM.

The display device may include an outermost dam ADM, which is a dam that serves as a pedestal for hanging a mask during a mask process on the outside of the first dam DM1. Due to the cross-sectional structure, the upper surface of the lower layer of the dam may have a longer length in the planar direction than the lower surface of the upper layer. The cross-sectional shape of each layer may have a trapezoidal shape in which two trapezoidal shapes are stacked as a whole. However, it is not necessarily limited to such an embodiment, and may have a different structure.

The outermost dam ADM may have a double layer structure. In an embodiment, the lower layer is the via hole layer VIA and the upper layer is a pixel defining layer PDL.

The embodiment of FIG. 3 may include a first capping layer IL1 on an upper portion of the second inorganic encapsulation layer EIL2. Although not shown in FIG. 4, the first capping layer IL1 covering the bank may cover the side surface of the bank and may contact the second inorganic encapsulation layer EIL2 at the end of the bank. The first capping layer IL1 and the second inorganic encapsulation layer EIL2 extend to the upper portion of the outermost dam ADM while in contact with each other.

In order to improve bonding strength between the first capping layer IL1 and the second inorganic encapsulation layer EIL2, the first capping layer IL1 may include same material as the second inorganic encapsulation layer EIL2. For example, the first capping layer IL1 may include SiNₓ. This improved bonding can effectively prevent penetration of moisture or oxygen from the outside.

An upper portion of the first capping layer IL1 may include a low refractive layer LR. In the non-display area of the display device, the matrix part of the low refractive layer LR may serve to cover and flatten the portion between the stacked structure on the display area and the outermost dam ADM. However, since the low refractive layer LR contains an organic material, it can receive moisture and oxygen penetration when exposed to the outside, so it is disposed only in the inner area of the outermost dam ADM, and the upper portion and side of the low refractive layer LR are sealed by inorganic layers. For example, in the embodiment of FIG. 4, the low refractive layer LR has a structure in which upper and side portions are covered by the first capping layer IL1 and the second capping layer IL2.

The second capping layer IL2 is disposed above the low refractive layer LR and covers the upper surface of the low refractive layer LR. The second capping layer IL2 extends to the upper portion of the outermost dam ADM and is in contact with the first capping layer IL1 at the upper portion of the outermost dam ADM.

The second capping layer IL2 may include same material as the first capping layer IL1. For example, the second capping layer IL2 may include SiNₓ. Accordingly, bonding strength between the first capping layer IL1 and the second capping layer IL2 is improved, and penetration of external moisture or oxygen may be effectively prevented.

A color filter layer CF may be disposed on the upper portion of the second capping layer IL2, and the planarization layer OC covers the upper portion and the end of the color filter layer CF. However, since the planarization layer OC contains an organic material, it can receive moisture and oxygen penetration when exposed to the outside, so it is disposed only in the inner area of the outermost dam ADM, and the upper and side surfaces of the planarization layer OC are sealed by inorganic layers. For example, in the embodiment of FIG. 4, the planarization layer OC has a structure in which the upper and end portions are covered by the second capping layer IL2 and the first upper inorganic layer AEIL1.

A first upper inorganic layer AEIL1 may be disposed on the planarization layer OC to cover the planarization layer OC. In addition, since the first upper inorganic layer AEIL1 is connected to the upper portion of the outermost dam ADM, it has a structure in contact with the second capping layer IL2 disposed below the first upper inorganic layer AEIL1 from the upper portion of the outermost dam ADM. The first upper inorganic layer AEIL1 may be formed by a chemical vapor deposition method CVD.

The first upper inorganic layer AEIL1 may be a single layer or a stacked layer including a metal oxide or a metal nitride. Specifically, the first upper inorganic layer AEIL1 may include any one of SiNₓ, Al₂O₃, SiO₂, and TiO₂. In particular, it may include the same material as the second capping layer IL2. For example, the first upper inorganic layer AEIL1 may include SiNₓ. Accordingly, the bonding strength between the first upper inorganic layer AEIL1 and the second capping layer IL2 is improved, and penetration of external moisture or oxygen can be effectively prevented.

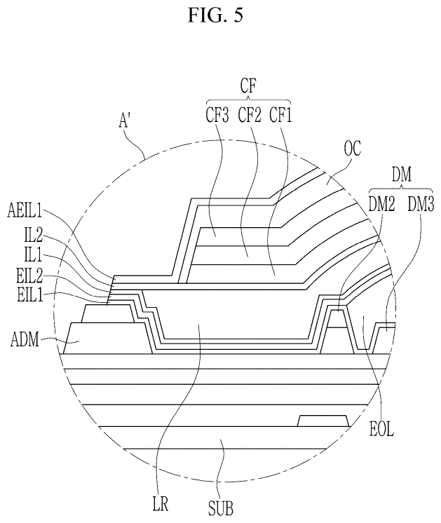

Hereinafter, a dam structure of a display panel according to an embodiment will be described in more detail with reference to FIG. 5. FIG. 5 is a cross-sectional view of an embodiment including fewer dams compared to embodiment of FIG. 3. This configuration relates to a display device including two or more dams in contact with the lower encapsulation layer dam.

At least one inner dam DM is disposed on the substrate SUB at the end portion of the organic encapsulation layer EOL. The inner dam DM may have a single-layer or a double-layer structure. The inner dam DM may be filled with the same organic material as the via hole layer VIA and/or the organic encapsulation layer EOL. However, it is not necessarily limited to such an embodiment, and may include a different structure or material.

In an embodiment (part A′ in the drawing), the dam DM includes a second dam DM2 composed of a double layer, the lower layer of the second dam DM2 is a via hole layer VIA and the upper layer is a pixel defining layer PDL. Due to the shape of the second dam DM2, the upper surface of the lower layer may have a longer length in the planar direction than the lower surface of the upper layer. In addition, each layer of the second dam DM2 consisting of a double layer has a trapezoidal cross-sectional shape and may have a trapezoidal shape as a whole.

The inner dam DM may limit the formation area of the organic material filled with the inkjet process in the organic encapsulation layer EOL. For example, an embodiment may include the second dam DM2. The third dam DM3 may be disposed on the display area inside of the second dam DM2, which is disposed at the end portion of the organic encapsulation layer EOL. The second dam DM2 and the third dam DM3 may also be filled with the same material as the first dam DM1.

In an embodiment of FIG. 5 (part A′ in the drawing), the display device includes the third dam DM3 disposed between the second dam DM2 and the light emitting element ED without the first dam.

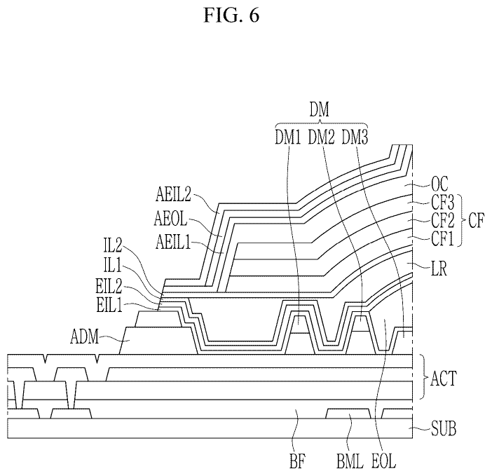

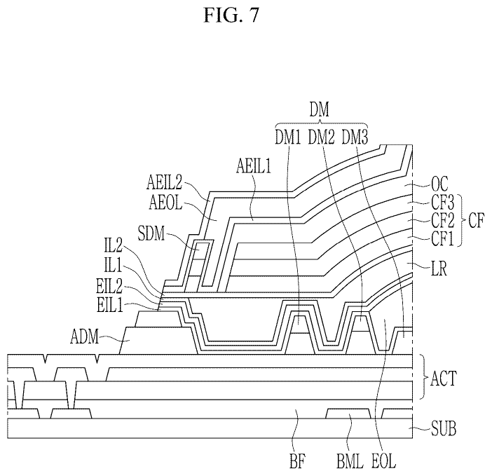

Hereinafter, a structure of a non-display area of a display panel according to another embodiment will be described in more detail with reference to FIGS. 6 and 7. FIGS. 6 and 7 are embodiments modified to include a plurality of layers from the embodiment of FIG. 3 having an upper encapsulation layer composed of a single layer. Hereinafter, descriptions of the same components as those described in FIGS. 3 and 4 will be omitted to avoid redundancy.

First, a structure of a display device having a plurality of upper encapsulation layers will be described with reference to FIG. 6.

Although not explicitly depicted, the upper encapsulation layer may include a plurality of inorganic layers and organic layers alternately disposed to protect the planarization layer OC layer from external moisture and oxygen. Accordingly, the upper encapsulation layer may include a sandwich structure in which at least one organic layer is inserted between at least two inorganic layers. An additional inorganic layer and an organic layer may be repeatedly disposed as needed, and the number of alternating times between the inorganic layer and the organic layer is not limited.

The embodiment of FIG. 6 includes a multi-layered structure in which a planarization layer OC, a first upper inorganic layer AEIL1, an upper organic layer AEOL, and a second upper inorganic layer AEIL2 are sequentially disposed.

Since the upper organic layer AEOL is an organic layer, it may be infiltrated by moisture and air when exposed to the outside, so it is disposed inside of the outermost dam ADM. That is, the upper organic layer AEOL does not contact the first upper inorganic layer AEIL1 at the upper portion of the outermost dam ADM.

Like the organic encapsulation layer EOL, the upper organic layer AEOL may include any one of epoxy, acrylate, and urethane acrylate, but is not limited thereto and may be changed to various materials according to design.

The second upper inorganic layer AEIL2 is disposed around the upper organic layer AEOL. The second upper inorganic layer AEIL2 may include, for example, SiNₓ, and may be formed by chemical vapor deposition CVD in the same manner as the first upper inorganic layer AEIL1.

The second upper inorganic layer AEIL2 is in contact with the first upper inorganic layer AEIL1 at the upper portion of the outermost dam ADM. Accordingly, the upper organic layer AEOL is not exposed to the outside.

Next, referring to FIG. 7, the structure of a display device that further includes a dam that limits the formation area of the upper organic layer in a display device having multiple upper encapsulation layers.

The display device having a plurality of upper inorganic encapsulation layers may further include a stopper dam SDM on the outer surface of the upper organic layer AEOL. Since the stopper dam SDM may be disposed in a space defined by the first upper inorganic layer AEIL1 and the second upper inorganic layer AEIL2, it is disposed inside of the outermost dam ADM. The first upper inorganic layer AEIL1 and the second upper inorganic layer AEIL2 may contact each other above the outermost dam ADM adjacent to the stopper dam SDM.

The stopper dam SDM may include a monomer material. In an embodiment, the stopper dam (SDM) may consist of three layers. The internal material constituting the triple layer is the same material as the color filter layer CF, and may be a first color filter CF1, a second color filter CF2, and a third color filter CF3. However, it is not necessarily limited to such an embodiment and may be configured in a different structure.

The stopper dam SDM serves to limit a region in which the upper organic layer AEOL is formed. Since the upper organic layer AOL may be injected onto the display device by an inkjet method in a process, the upper organic layer AOL may be disposed between the first upper inorganic layer AIL1 or the second upper organic layer AIL2 outside the outermost dam ADM during a process. Therefore, a structure that prevents organic material from flowing over the outside of the upper organic layer AEOL has been added. In addition, the stopper dam SDM may serve to limit the formation area so that the contents of the planarization layer OC containing organic materials do not flow to the outside of the outermost dam SDM.

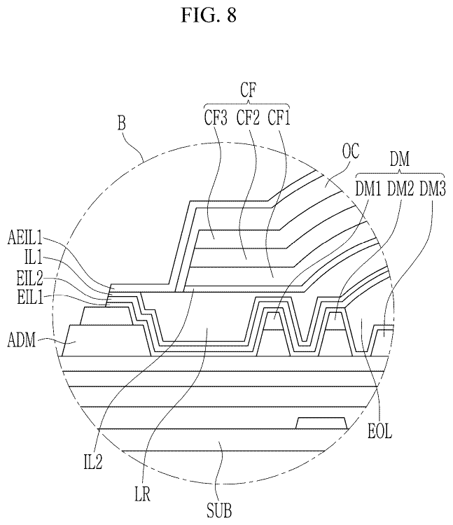

Hereinafter, a structure of a non-display area of a display panel according to an embodiment different from that of FIG. 3 will be described in more detail with reference to FIG. 8. FIG. 8 is a cross-sectional view of a non-display portion of a display device including a B portion.

Part B of FIG. 8 illustrates a display device having a structure in which a first capping layer and an upper inorganic layer contact each other at an upper part of an outermost dam. Hereinafter, the content explained above in reference to FIG. 3 will be omitted for FIG. 8 if redundant.

The second capping layer IL2 is disposed on the low refractive layer LR and covers the low refractive layer LR. However, since the covering surface does not extend to the upper portion of the outermost dam ADM, the second capping layer IL2 may not be disposed above the outermost dam ADM.

An upper inorganic layer AEIL1 is disposed on the planarization layer OC. The upper inorganic layer AEIL1 may cover an upper portion of a portion of the low refractive layer LR that is not covered with the planarization layer OC and the second capping layer IL2. The upper inorganic layer AEIL1 serves to protect the low refractive layer LR and the planarization layer OC, which may contain organic materials, from being exposed to the external environment, thus safeguarding the low refractive layer LR and the planarization layer OC from external moisture and humidity.

The upper inorganic layer AEIL1 includes at least a single layer of a first upper inorganic layer, and may include a first upper inorganic layer, an upper organic layer, and a second upper inorganic layer. Also, the number of inorganic layers is not limited.

When the upper inorganic layer AEIL1 includes a plurality of inorganic layers, the display device may further include a stopper dam for limiting an area in which the upper organic layer is disposed inside of the outermost dam ADM.

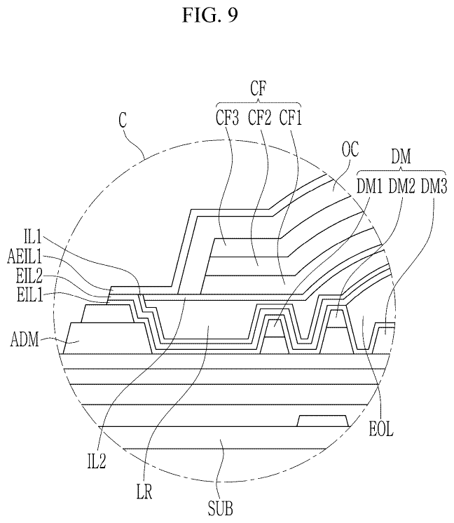

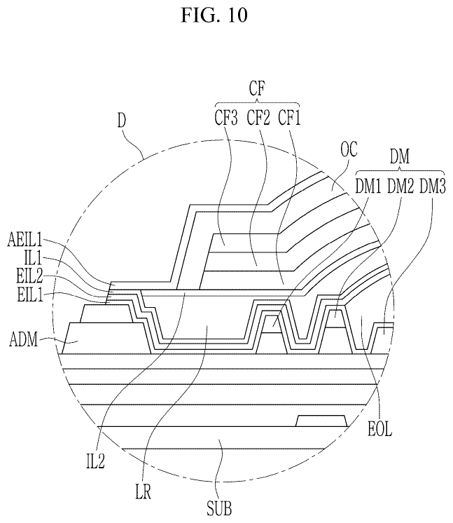

Hereinafter, an embodiment that may be modified from FIG. 3 will be described with reference to FIGS. 9 and 10. FIGS. 9 to 10 are cross-sectional views of a display device including a modified structure according to an embodiment. Hereinafter, the contents described in FIG. 3 will be omitted to avoid redundancy.

Part C of FIG. 9 shows a display device having a structure in which a first inorganic encapsulation layer and a first upper inorganic layer contact each other at an upper portion of an outermost dam. Hereinafter, the structures described in reference to FIG. 3 that apply to FIG. 9 will not be repeated.

In the embodiment of FIG. 9, the first capping layer IL1 and the second capping layer IL2 are in contact with the low refractive layer LR. The first capping layer IL1 and the second capping layer IL2 may extend to the upper surface of the outermost dam ADM and may not be disposed. However, since the low refractive layer LR is surrounded by the first capping layer IL1 and the second capping layer IL2 that are connected to each other, the low refractive layer LR is not exposed to the outside.

Although not shown in the drawings, in the present embodiment, the first inorganic encapsulation layer EIL1, the second inorganic encapsulation layer EIL2, and the first upper inorganic layer AEIL1 may form a structure that is in contact with the upper surface of the outermost dam ADM without covering the outermost dam ADM.

A part D of FIG. 10 is a cross-sectional view illustrating a cross-section of a display device in which the first capping layer IL1 and the second capping layer IL2 are in contact near an end portion of the low refractive layer LR and the first capping layer IL1 extends to an edge portion of the multilayer structure covering part of the outermost dam ADM.

In FIG. 10, the first capping layer IL1 extends to the upper surface of the outermost dam ADM. Therefore, it is in contact with the first upper inorganic layer AEIL1 disposed on the upper side in the thickness direction based on the first capping layer IL1, and the second inorganic encapsulation layer EIL2 disposed on the lower side in the thickness direction, also based on the first capping layer IL1, on the outermost dam ADM.

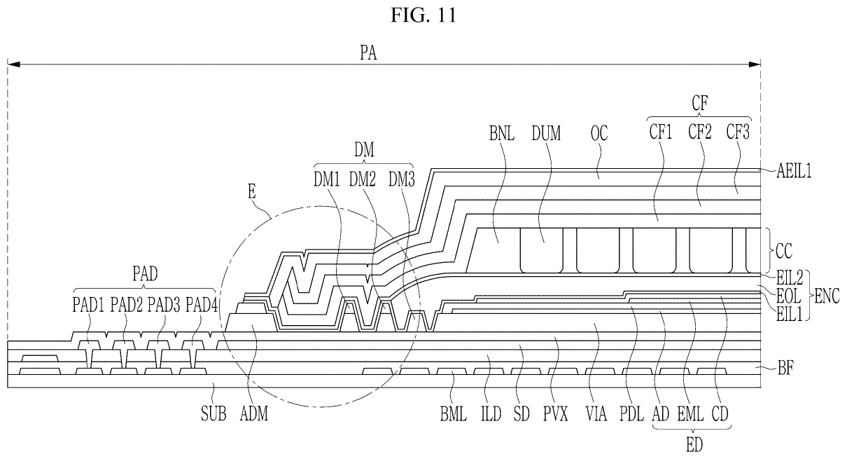

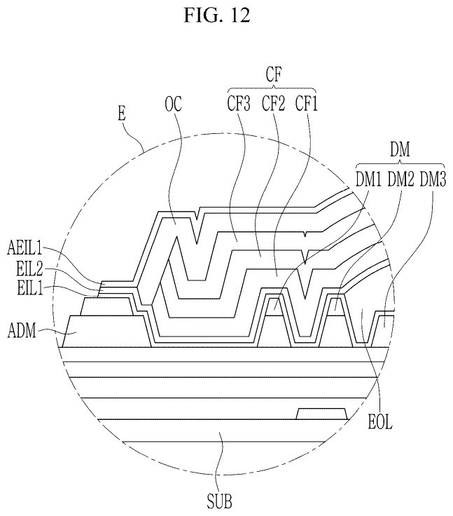

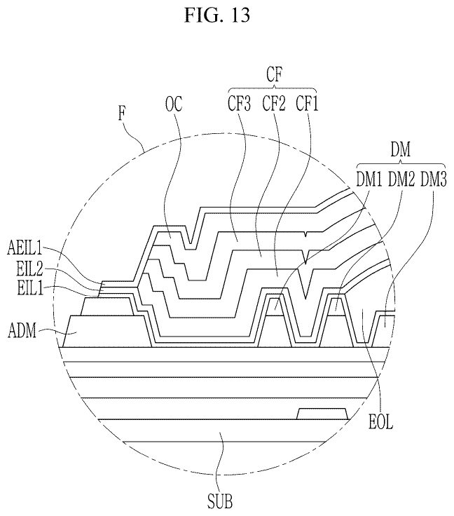

Hereinafter, a structure of a non-display area of a display panel according to an embodiment that does not include a low refractive layer will be described with reference to FIGS. 11 to 15. FIG. 11 is a cross-sectional view of a non-display part of a display device according to an embodiment, and FIG. 12 is an enlarged cross-sectional view of part E of FIG. 11. Also, FIGS. 13 to 15 are cross-sectional views according to another embodiment related to FIG. 10. Hereinafter, a description of the same structure as that of FIG. 3 will be omitted.

Hereinafter, a cross-sectional structure of a display panel according to an embodiment that does not include a low refractive layer will be described with reference to FIG. 11. FIG. 11 is a cross-sectional view of a non-display portion of a display device including an E portion.

A color filter layer CF is disposed on the bank BNL. A layer may be disposed on the second dam DM2 and the third dam DM3, without including the encapsulation layer ENC and the layer that flattens the area between the outermost dams ADM, disposed in the non-display direction, based on the encapsulation layer ENC. However, this is not a limitation of the present embodiment, and the first dam DM1 and/or the second dam DM2 may be omitted.

A planarization layer OC is disposed on the upper portion of the third color filter CF3 and the upper side surface of the end portion of the color filter layer CF. Since the planarization layer OC includes an organic material, it is disposed on the inner surface of the outermost dam ADM.

A first upper inorganic layer AEIL1 is disposed on the planarization layer OC.

FIG. 12 is an enlarged view of the cross section part E.

The first upper inorganic layer AEIL1 covers the upper portion of the planarization layer OC, and may be in contact with the second inorganic encapsulation layer EIL2 at the upper portion of the outermost dam ADM. In the first upper inorganic layer AEIL1 and the second inorganic encapsulation layer EIL2, the planarization layer OC disposed inside of the outermost dam ADM avoids being exposed to the outside. This allows the organic layer layer to protect from external moisture and oxygen.

FIG. 13 is a diagram showing an embodiment including cross section part F in which the structure of the planarization layer is modified from the structure of part E of FIG. 12. The structure of the display panel including part F is to be described. Any redundant description that was provided in reference to FIG. 11 will be omitted.

In the embodiment of part F, a planarization layer OC is disposed above the third color filter CF3. However, the planarization layer OC does not extend to cover the upper surface of the color filter layer CF. Since the color filter layer CF may include an organic material, it is disposed inside of the outermost dam ADM and enclosed by the first upper inorganic layer AEIL1.

The first upper inorganic layer AEIL1 covers the upper and side surfaces of the color filter layer CF and the planarization layer OC, and extends to partially cover the outermost dam ADM. The first upper inorganic layer AEIL1 may be in contact with the second inorganic encapsulation layer EIL2 that also partially covers the outermost dam ADM.

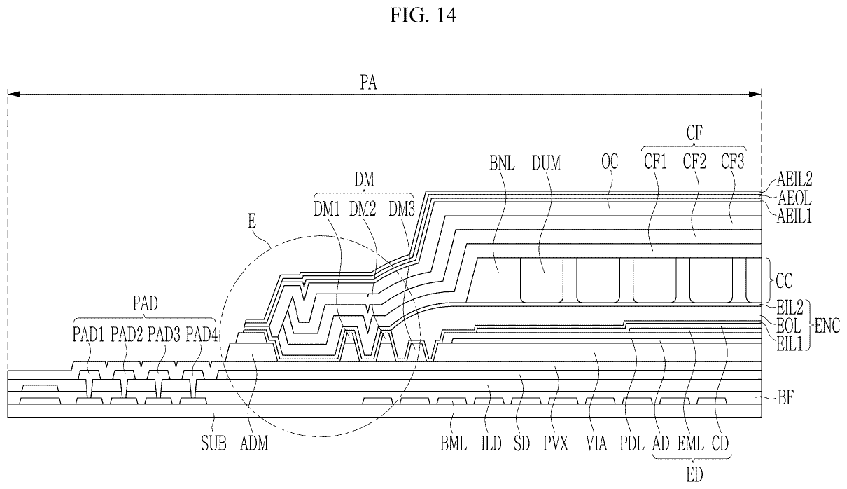

FIG. 14 is a view showing an embodiment modified to include a plurality of upper inorganic layers at the outermost side in the structure of part E of FIG. 12.

In an embodiment of FIG. 14, a first upper inorganic layer AEIL1, an upper organic layer AEOL, and a second upper inorganic layer AEIL2 are included in an upper portion of the display device.

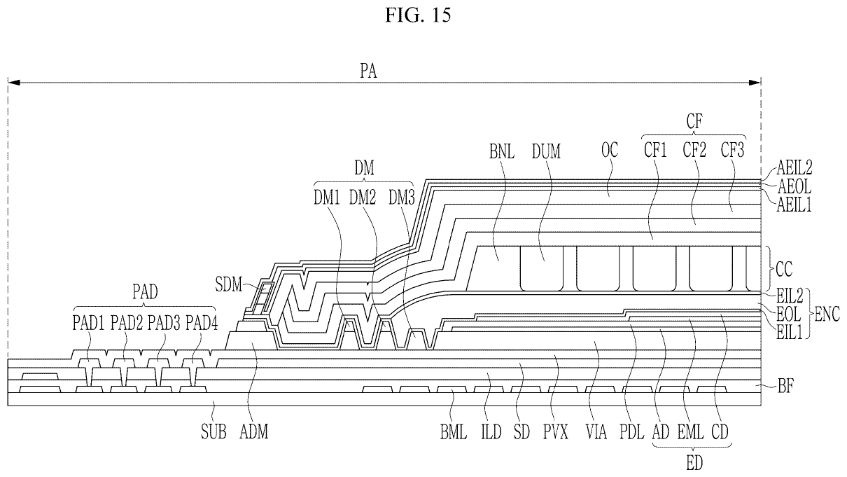

FIG. 15 is a view showing an embodiment modified to further include a stopper dam limiting an upper organic layer formation region in the structure of part E of FIG. 14.

The stopper dam SDM of FIG. 15 is disposed outside the upper organic layer AEOL. The stopper dam SDM may serve to prevent the organic material from overflowing and limit the formation area so that the organic material of the planarization layer OC does not flow to an area outside of the outermost dam SDM.

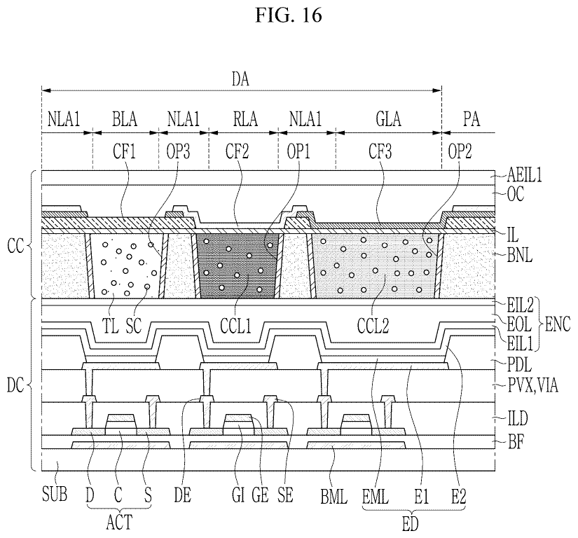

Hereinafter, a structure of the display area DA of the display panel according to an embodiment of FIG. 3 will be described with reference to FIG. 16. FIG. 16 is a cross-sectional view of a display portion of a display panel according to an embodiment. Any redundant description that is provided above in reference to FIG. 3 will be omitted.

The display area DA according to an embodiment may have the same structure as the stacked structure of the non-display area PA described in FIG. 3.

A bottom metal layer BML and a buffer layer BF may be disposed on the substrate SUB.

A gate electrode GE is disposed above the buffer layer BF. The gate electrode GE may be a multilayer in which a metal layer including at least one of copper Cu, a copper alloy, aluminum Al, an aluminum alloy, molybdenum Mo, and a molybdenum alloy is stacked.

An interlayer insulating layer ILD is disposed on the gate electrode GE and the gate insulating layer GI. The source electrode SE and the drain electrode DE are connected to the source region S and the drain region D of the semiconductor layer ACT through openings disposed in the interlayer insulating layer ILD, respectively.

A passivation PVX and a via hole layer VIA is disposed on the interlayer insulating layer ILD, the source electrode SE, and the drain electrode DE. Since the passivation PVX and the via hole layer VIA covers and planarizes the interlayer insulating layer ILD, the source electrode SE, and the drain electrode DE. The first electrode E1 may be disposed on the passivation PVX.

A first electrode E1 is disposed on the passivation PVX. The first electrode E1 is connected to the drain electrode DE through the opening of the passivation PVX.

The first electrode E1 is disposed at the base of the pixel opening part of the pixel defining layer PDL. The light emission layer EML disposed on the first electrode E1 may include a small molecule organic material or a polymer organic material such as Poly 3,4-ethylenedioxythiophene PEDOT.

The light emission layer EML may be disposed on the first electrode E1 overlapping the pixel opening part of the pixel defining layer PDL and may also be disposed on the side surface or above the pixel defining layer PDL. The light emission layer EML may be a multilayer further including at least one of a hole injection layer, a hole transporting layer, an electron transport layer, and an electron injection layer.

A second electrode E2 is disposed on the light emission layer EML. The second electrode may be disposed across a plurality of pixels and may receive a common voltage through a common voltage transfer unit (not shown) in the non-display area PA.

Here, the first electrode E1 may be an anode that is a hole injection electrode, and the second electrode E2 may be a cathode that is an electron injection electrode. However, the embodiment is not necessarily limited thereto, and the first electrode E1 may be the cathode and the second electrode E2 may be the anode depending on the driving method of the organic light emitting display device.

The driving transistor consisting of the gate electrode GE, the semiconductor layer ACT, the source electrode SE, and the drain electrode DE is connected to the first electrode E1 to supply a driving current to each light emitting element ED. In addition to the driving transistor shown in FIG. 16, the display device according to the present embodiment may further include a switching transistor (not shown) connected to a data line and transmitting a data voltage in response to a scan signal, and a compensation transistor (not shown) connected to the driving transistor and compensating for a threshold voltage of the driving transistor in response to a scan signal.

The display device may be incorporated into various electronic devices including but not limited to portable electronic devices such as mobile phones, smartphones, tablet personal computers (PCs), mobile communication terminals, electronic notebooks, e-books, portable multimedia players (PMPs), navigations, and ultra mobile PCs (UMPCs), but also televisions (TVs), laptops, monitors, billboards, Internet of Things (IoT), or the like. According to an embodiment, the display device may also be used in wearable electronic devices such as smart watches, watch phones, glasses-type displays, or head mounted displays (HMDs). According to an embodiment, the display device may also be used in vehicle dashboards, center information displays (CIDs) of the center fascia or dashboards of vehicles, mirror displays that replace the side view mirrors of vehicles, and display screens arranged on the rear sides of front seats to serve as entertainment devices for back seat passengers of vehicles.

Although the embodiments of the present disclosure have been described in detail above, the scope of the present disclosure is not limited thereto, and various modifications and improvements of those skilled in the art using the basic concept of the present disclosure defined in the following claims also belong to the scope of the present disclosure.

What is claimed is:

1. A display device comprising:
a substrate;
a plurality of light emitting elements disposed in a display area on the substrate;
an encapsulation layer that encloses the plurality of light emitting elements;
a color conversion layer and a bank disposed on the encapsulation layer;
a first capping layer disposed on the color conversion layer and the bank;
a low refractive layer disposed on the color conversion layer and the bank;
a second capping layer disposed on the low refractive layer;
a color filter layer disposed on the second capping layer;
a planarization layer disposed on the color filter layer;
a first upper inorganic encapsulation layer disposed on the planarization layer; and
an inner dam and an outermost dam disposed in a non-display area of the substrate,
wherein the encapsulation layer comprises an organic encapsulation layer disposed between a first inorganic encapsulation layer and a second inorganic encapsulation layer,
wherein the color filter layer and the planarization layer are disposed inside of the outermost dam,
wherein the first upper inorganic encapsulation layer covers a side surface and an end portion of the planarization layer, and
wherein the first upper inorganic encapsulation layer contacts the second capping layer at an end portion of the planarization layer.

2. The display device of claim 1, wherein
the low refractive layer is disposed inside of the outermost dam, and
the first capping layer and the second capping layer contact each other at an end portion of the low refractive layer.

3. The display device of claim 2, further comprising
an upper organic encapsulation layer disposed on the first upper inorganic encapsulation layer; and
a second upper inorganic encapsulation layer disposed on the upper organic encapsulation layer,
wherein the upper organic encapsulation layer is disposed inside of the outermost dam, and
wherein the second upper inorganic encapsulation layer covers an end portion of the upper organic encapsulation layer.

4. The display device of claim 3, wherein:
the first upper inorganic encapsulation layer and the second upper inorganic encapsulation layer are in contact with each other at an end portion of the organic encapsulation layer.

5. The display device of claim 4, further comprising:
a stopper dam disposed in a non-display area adjacent to the upper organic encapsulation layer,
wherein the upper organic encapsulation layer is disposed inside of the stopper dam, and
wherein the second upper inorganic encapsulation layer covers an upper surface and a side surface of the stopper dam.

6. The display device of claim 2, wherein:
the first capping layer covers the bank and the color conversion layer and a side surface of the bank, and
wherein the first capping layer and the second inorganic encapsulation layer contact each other at an end portion of the bank.

7. The display device of claim 6, wherein:
the second inorganic encapsulation layer covers an end portion of the organic encapsulation layer, and
wherein the first inorganic encapsulation layer and the second inorganic encapsulation layer contact an upper surface of the inner dam.

8. The display device of claim 7, further comprising at least one of:
Another inner dam disposed in the non-display area outside of the inner dam; and
an extra inner dam disposed in the non-display area inside of the dam.

9. A display device comprising:
a substrate;
a plurality of light emitting elements disposed in a display area on the substrate;
an encapsulation layer that encloses the plurality of light emitting elements;
a color conversion layer and a bank disposed on the encapsulation layer;
a first capping layer disposed on the color conversion layer and the bank;
a low refractive layer disposed on the color conversion layer and the bank;
a second capping layer disposed on the low refractive layer;
a color filter layer disposed on the second capping layer;
a planarization layer disposed on the color filter layer;
a first upper inorganic encapsulation layer disposed on the planarization layer; and
a dam and an outermost dam disposed in a non-display area of the substrate,
wherein the encapsulation layer comprises an organic encapsulation layer disposed between a first inorganic encapsulation layer and a second inorganic encapsulation layer,
wherein the planarization layer and the low refractive layer are disposed inside of the outermost dam, and
wherein the first upper inorganic encapsulation layer contacts the first capping layer.

10. The display device of claim 9, wherein
the second capping layer and the planarization layer contact each other.

11. The display device of claim 10, wherein
the first capping layer covers the bank and the color conversion layer and a side surface of the bank, and
wherein the first capping layer and the second inorganic encapsulation layer contact each other.

12. The display device of claim 11, wherein
the second inorganic encapsulation layer covers an end portion of the organic encapsulation layer, and
wherein the first inorganic encapsulation layer and the second inorganic encapsulation layer contact each other at an upper portion of the inner dam.

13. The display device of claim 10, further comprising:
an upper organic encapsulation layer disposed on the first upper inorganic encapsulation layer; and
a second upper inorganic encapsulation layer disposed on the upper organic encapsulation layer,
wherein the upper organic encapsulation layer is disposed inside of the outermost dam,
wherein second upper inorganic encapsulation layer covers an end portion of the upper organic encapsulation layer, and
wherein the first upper inorganic encapsulation layer and the second upper inorganic encapsulation layer contact each other at an end portion of the organic encapsulation layer.

14. The display device of claim 13, further comprising:
a stopper dam disposed in the non-display area adjacent to the upper organic encapsulation layer,
wherein the upper organic encapsulation layer is disposed inside of the stopper dam, and
wherein the second upper inorganic encapsulation layer covers an upper surface and a side surface of the stopper dam.

15. The display device of claim 14, wherein:
the planarization layer is disposed inside of the stopper dam.

16. An electronic device comprising:
a substrate;
a plurality of light emitting elements disposed in a display area on the substrate;
an encapsulation layer that encloses the plurality of light emitting elements;
a color conversion layer and a bank disposed on the encapsulation layer;
a color filter layer disposed on the bank;
a planarization layer disposed on the color filter layer;
a first upper inorganic encapsulation layer disposed on the planarization layer; and
an inner dam and an outermost dam disposed in a non-display area of the substrate,
wherein the encapsulation layer comprises an organic encapsulation layer disposed between a first inorganic encapsulation layer and a second inorganic encapsulation layer,
wherein the planarization layer is disposed inside of the outermost dam, and
wherein the first upper inorganic encapsulation layer contacts the second inorganic encapsulation layer at an end portion of the planarization layer.

17. The electronic device of claim 16, wherein:
the second inorganic encapsulation layer covers a side surface of the organic encapsulation layer, and
wherein the first inorganic encapsulation layer and the second inorganic encapsulation layer contact each other at an upper portion of the inner dam.

18. The electronic device of claim 17, wherein:
the color filter layer is disposed inside of the outermost dam, and
wherein the planarization layer covers an end portion of the color filter layer.

19. The electronic device of claim 16, further comprising:
an upper organic encapsulation layer disposed on the first upper inorganic encapsulation layer; and
a second upper inorganic encapsulation layer disposed on the upper organic encapsulation layer,
wherein the upper organic encapsulation layer is disposed inside of the outermost dam,
wherein the second upper inorganic encapsulation layer covers an end portion of the upper organic encapsulation layer, and
wherein the first upper inorganic encapsulation layer and the second upper inorganic encapsulation layer contact each other at an end portion of the planarization layer.

20. The electronic device of claim 19, further comprising:
a stopper dam disposed in the non-display area adjacent to the upper organic encapsulation layer,
wherein the upper organic encapsulation layer is disposed inside of the stopper dam, and
wherein the second upper inorganic encapsulation layer covers an upper surface and a side surface of the stopper dam.
